(19) United States
(12) Patent Application Publication
(10) Pub. No.: US 2026/0082721 A1
(43) Pub. Date: Mar. 19, 2026

(54) SEMICONDUCTOR APPARATUS, SEMICONDUCTOR APPARATUS MANUFACTURING METHOD, IMAGING APPARATUS, RADIATION IMAGING SYSTEM, AND EQUIPMENT

(71) Applicant: CANON KABUSHIKI KAISHA, Tokyo (JP)

(72) Inventor: KATSUHISA MOCHIZUKI, Kanagawa (JP)

(21) Appl. No.: 19/324,366

(22) Filed: Sep. 10, 2025

(30) Foreign Application Priority Data
Sep. 17, 2024 (JP) 2024-160022

(51) Int. Cl. H10F 39/00

(52) U.S. Cl. CPC H10F 39/811; H10F 39/018; H10F 39/804; H10F 39/809

(57) ABSTRACT

A semiconductor apparatus includes a first board and a second board. The first board includes an effective element region and a first electrode disposed between the effective element region and an outer edge of the first board, having a first member made of a resin and disposed on an outer edge side of the first board. The second board includes a second electrode disposed between a mounting position of the first board and an outer edge of the second board, having a second member made of a resin and disposed on an outer edge side of the second board. A third member that is made of a resin and is in contact with the first member and the second member is disposed between the first member and the second member, is not disposed closer to the effective element region than the first member is.

### BACKGROUND

### Field of the Technology

The present disclosure relates to a semiconductor apparatus in which a semiconductor chip and a circuit board are electrically connected by wire bonding, a semiconductor apparatus manufacturing method, and the like.

### Description of the Related Art

In a case where a semiconductor chip is mounted on a circuit board, a method of connecting an electric signal, a power supply, and the like using wire bonding is known. A method of sealing the entire semiconductor chip and a connected wire with a resin after connecting the wire in order to prevent peeling and disconnection of the wire is known.

According to a method described in JP H08-186137 A, a land of a semiconductor chip mounted on a board and an electrode of the board are connected by a bonding wire, and then a reinforcing resin is applied so as to be in contact with the wire and cured. After a position of the wire is stabilized by the reinforcing resin, a sealing resin is applied so as to entirely cover the semiconductor chip, the wire, and the reinforcing resin and is then cured, thereby sealing the entire semiconductor chip with the resin.

In recent years, a semiconductor chip has become multifunctional, and a semiconductor apparatus on which the semiconductor chip is mounted has been required to be downsized. Therefore, the semiconductor chip and the circuit board need to be connected at a small arrangement pitch using a large number of wires.

In the method described in JP H08-186137 A, the semiconductor chip, the wire, and the reinforcing resin are entirely covered with the sealing resin. For convenience of molding, a resin having a high viscosity is used as the sealing resin. However, in a case a resin having a high viscosity is used, bubbles and voids are likely to be generated between wires arranged at a small pitch or in a portion hidden by the reinforcing resin. When the sealing resin is solidified in a state in which bubbles or voids are present, a mechanical strength decreases, and a function of protecting the wire becomes insufficient, which may cause a problem. Therefore, a technology capable of suitably protecting a wire by using a resin in a semiconductor apparatus in which a semiconductor chip and a circuit board are connected by the wire has been required.

### SUMMARY

According to a first aspect of the present disclosure, a semiconductor apparatus includes a first board serving as a semiconductor chip and a second board including an electric circuit and on which the first board is mounted. The first board includes an effective element region and a first electrode disposed between the effective element region and an outer edge of the first board, having a first member made of a resin and disposed on an outer edge side of the first board with respect to the effective element region. The second board includes a second electrode disposed between a mounting position of the first board and an outer edge of the second board, having a second member made of a resin and disposed on an outer edge side of the second board with respect to the mounting position of the first board. A third member that is made of a resin and is in contact with the first member and the second member is disposed between the first member and the second member, is not disposed closer to the effective element region than the first member is, and is not disposed closer to the outer edge side of the second board than the second member is. The first electrode and the second electrode are electrically connected to each other via a wiring. A connection portion where the wiring and the first electrode are connected is covered with the first member or the third member. A connection portion where the wiring and the second electrode are connected is covered with the second member or the third member. In the wiring, an entire region from the connection portion for the first electrode to the connection portion for the second electrode is covered with a resin member including at least the third member.

According to a second aspect of the present disclosure, a semiconductor apparatus manufacturing method includes in this order, a mounting step of mounting a first board serving as a semiconductor chip and including an effective element region and a first electrode on a second board including a second electrode and an electric circuit, a connection step of electrically connecting the first electrode and the second electrode by a wiring, and a covering step of covering the wiring with a resin member. The first electrode is disposed between the effective element region and an outer edge of the first board. The second electrode is disposed between a position where the first board is mounted and an outer edge of the second board. The covering step includes disposing a first member made of a resin on an outer edge side of the first board with respect to the effective element region and curing the first member, disposing a second member made of a resin on an outer edge side of the second board with respect to the position where the first board is mounted and curing the second member, and disposing a third member made of a resin having a viscosity lower than a viscosity of the first member before curing and a viscosity of the second member before curing between the cured first member and the cured second member and curing the third member. A connection portion where the wiring and the first electrode are connected is covered with the first member or the third member. A connection portion where the wiring and the second electrode are connected is covered with the second member or the third member. In the wiring, an entire region from the connection portion for the first electrode to the connection portion for the second electrode is covered with a resin member including at least the third member.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic plan view of a semiconductor apparatus according to a first embodiment.

FIG. 2 is a schematic cross-sectional view showing a cross section of the semiconductor apparatus according to the first embodiment taken along line A-A shown in FIG. 1.

FIG. 3A is a view showing a stage where a first board 100 is bonded and fixed to a second board 200.

FIG. 3B is a view showing a stage in which a first electrode 110 and a second electrode 210 are electrically connected using a wiring 300.

FIG. 3C is a view showing a stage where an uncured second member 500 is disposed.

FIG. 3D is a view showing a stage where an uncured first member 400 is disposed.

FIG. 3E is a view showing a stage where the first member 400 and the second member 500 are cured by being irradiated with an ultraviolet ray 800.

FIG. 3F is a view showing a stage where an uncured third member 600 is disposed between the first member 400 and the second member 500 after curing.

FIG. 3G is a view showing a stage in which the third member 600 is cured by being irradiated with the ultraviolet ray 800.

FIG. 4 is a schematic cross-sectional view showing a cross section of a semiconductor apparatus according to a first example of a second embodiment taken along line A-A shown in FIG. 1.

FIG. 5 is a schematic cross-sectional view showing a part of a cross section of a semiconductor apparatus according to a second example of the second embodiment taken along line A-A shown in FIG. 1.

FIG. 6 is a schematic cross-sectional view showing a part of a cross section of a semiconductor apparatus according to a third example of the second embodiment taken along line A-A shown in FIG. 1.

FIG. 7 is a schematic cross-sectional view showing a cross section of a semiconductor apparatus according to a fourth example of the second embodiment taken along line A-A shown in FIG. 1.

FIG. 8 is a schematic cross-sectional view showing a cross section of a semiconductor apparatus according to a third embodiment taken along line A-A shown in FIG. 1.

FIG. 9 is a schematic cross-sectional view showing a cross section of a semiconductor apparatus according to a fourth embodiment.

FIG. 10 is a schematic plan view of a semiconductor apparatus according to a fifth embodiment.

FIG. 11 is a schematic cross-sectional view showing a cross section of the semiconductor apparatus according to the fifth embodiment taken along line B-B shown in FIG. 10.

FIG. 12A is a schematic diagram for describing equipment including an imaging apparatus (semiconductor apparatus) according to a sixth embodiment.

FIG. 12B is a diagram showing an example of a photoelectric conversion system related to an in-vehicle camera.

FIG. 12C is a diagram showing the photoelectric conversion system in the case of imaging an area in front of a vehicle.

FIG. 13A is a schematic diagram showing equipment serving as a radiation imaging system according to a seventh embodiment.

FIG. 13B is a schematic diagram showing a configuration of a transmission electron microscope serving as the radiation imaging system according to the seventh embodiment.

### DESCRIPTION OF THE EMBODIMENTS

Therefore, it is also conceivable to use a resin having a low viscosity for the sealing resin to entirely cover the semiconductor chip, the wire, and the reinforcing resin. However, since a resin having a low viscosity is likely to spread, it may be difficult to provide the sealing resin with a thickness sufficient to protect the wire. In addition, when a large amount of resin having a low viscosity is applied in order to achieve the thickness, the sealing resin overflows and spreads in an area outside the reinforcing resin, and contamination may occur. Therefore, there is a possibility that quality and reliability of the semiconductor apparatus deteriorate. JP H08-186137 A also describes a method of defining a cavity so as to enclose the semiconductor chip, the wire, and the reinforcing resin by using a mold, and pouring a molten resin into the cavity, but such a method has a problem that the apparatus becomes large.

Furthermore, in the method of sealing the entire semiconductor chip with the sealing resin as in JP H08-186137 A, for example, in a case where the semiconductor chip on which a photoelectric conversion element is formed is mounted on the circuit board, a light receiving surface of the photoelectric conversion element is covered with the resin, as a result of which a function of the photoelectric conversion element cannot be sufficiently performed. In addition, in the method of sealing the entire semiconductor chip with the resin, in a case where the semiconductor chip on which a display element or a light emitting element is formed is mounted on the circuit board, the display element or the light emitting element is covered with the resin, as a result of which functions of the display element or the light emitting element cannot be sufficiently performed. As described above, there are many semiconductor apparatuses for which it is not realistic to apply the method of JP H08-186137 A.

Semiconductor apparatuses, semiconductor apparatus manufacturing methods, and the like according to embodiments of the present disclosure will be described with reference to the drawings. The embodiments described below are merely examples, and for example, detailed configurations can be appropriately changed and implemented by those skilled in the art without departing from the gist of the present disclosure.

In the drawings referred to in the following embodiments and description, elements denoted by the same reference signs have similar functions unless otherwise specified. In the drawings, in a case where a plurality of the same elements are arranged, reference signs and a description thereof may be omitted.

In addition, the drawings may be schematic for convenience of illustration and description, and thus, the shape, size, arrangement, and the like of elements in the drawings may not strictly match those of actual ones. In addition, “XX or more and YY or less” or “XX to YY” representing a numerical range means a numerical range including end points XX (lower limit) and YY (upper limit) unless otherwise specified. When numerical ranges are described in stages, the upper limit and the lower limit of each numerical range can be arbitrarily combined.

Note that seeing through the semiconductor apparatus from a direction (Z direction) perpendicular to a main surface of a semiconductor chip may be referred to as a plan view of the semiconductor apparatus.

### First Embodiment

### Configuration of Semiconductor Apparatus

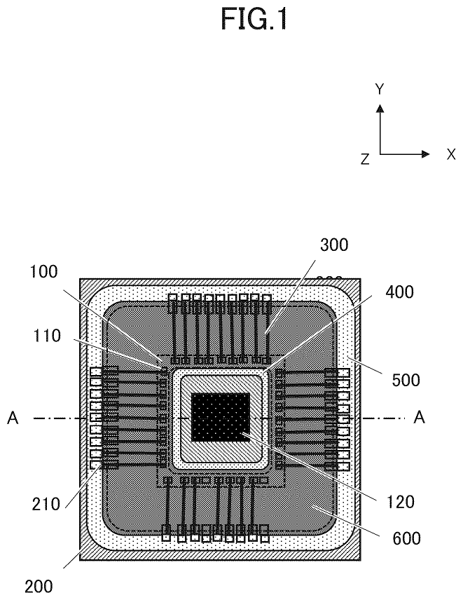

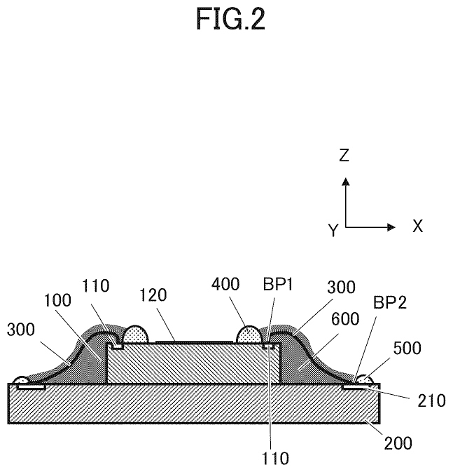

FIG. 1 is a schematic plan view of a semiconductor apparatus according to a first embodiment, and FIG. 2 is a schematic cross-sectional view showing a cross section of the semiconductor apparatus taken along line A-A shown in FIG. 1. The semiconductor apparatus according to the present embodiment includes a first board 100 serving as a semiconductor chip and a second board 200 serving as a circuit board, and the first board 100 is mounted at a predetermined position (mounting position) on the second board. Also, in a case where the semiconductor apparatus is cut in a direction that passes through the center of the semiconductor apparatus shown in FIG. 1 and is orthogonal to line A-A, a cross-sectional view similar to FIG. 2 may be obtained.

The first board 100 serving as the semiconductor chip is a board on which a semiconductor element is formed, and may be, for example, a board on which a solid-state imaging element that captures an optical image of visible light, infrared light, ultraviolet light, or the like, a radiation detection element that captures a radiation image, a display element that displays an image, or a light emitting element is formed. In an effective element region 120 of the first board 100, the semiconductor element such as a photoelectric conversion element or the light emitting element is provided according to a function of the semiconductor apparatus. In order not to interfere with such a function of the semiconductor element, a first member 400, a second member 500, and a third member 600 described below are not disposed in the effective element region 120.

A plurality of first electrodes 110 made of, for example, AL-Cu or AL-Si, are provided in the vicinity of an outer edge of a main surface of the first board 100. A wiring 300 made of, for example, a gold wire, a copper wire, or an AL wire is wire-bonded to the first electrode 110.

The first electrode 110 of the first board 100 is electrically connected to a second electrode 210 of the second board 200 via the wiring 300. As shown in FIG. 2, a connection portion where the wiring 300 is bonded to the first electrode 110 is defined as a first connection point BP1, and a connection portion where the wiring 300 is bonded to the second electrode 210 is defined as a second connection point BP2. The wiring 300 functions as an electric signal wiring or a power supply wiring.

The second board 200 is the circuit board using, for example, ceramic or glass epoxy as a base material. The second board 200 includes, for example, an electric circuit for driving or controlling the semiconductor element included in the first board 100 and exchanging a signal with the semiconductor element. The second board 200 includes an island portion for mounting the first board 100 at a central portion, and the first board 100 is fixed to the island portion.

In the second board 200, a plurality of second electrodes 210 made of a material that can be wire-bonded to the wiring 300, for example, Au, Cu, Ni, or AL, are formed at positions separated from the first board 100 by a predetermined interval. The second electrode 210 is disposed, for example, in the vicinity of an outer edge of a main surface of the second board 200 in order to prevent excessive tension from being applied due to excessive bending of the wire-bonded wiring 300.

In the first board 100, the first member 400 made of a resin is provided between the effective element region 120 and the first connection point BP1. In the example shown in FIG. 2, the first member 400 is disposed at a position not overlapping the effective element region 120 and the first electrode 110. As long as the first member 400 does not overlap the effective element region 120, the first member 400 may overlap a part of the first electrode 110.

In the second board 200, the second member 500 made of a resin is provided on a side opposite to the first board 100 with respect to the second connection point BP2, that is, on an outer edge side of the second board 200 with respect to the second connection point BP2. In the example shown in FIG. 2, the second member 500 is disposed at a position overlapping a part of the second electrode 210. However, the second member 500 may also be disposed at a position not overlapping the second electrode 210 on a further outer edge side of the second board 200.

The first member 400 and the second member 500 are made of a resin such as an acrylic resin, an epoxy resin, or a silicone resin. A method of manufacturing the first member 400 and the second member 500 will be described below. The first member 400 and the second member 500 can be manufactured by applying an uncured resin to a predetermined position by a dispenser of any type such as an air pulse type, a jet type, or a volumetric type, and then curing (solidifying) the uncured resin.

The third member 600 made of a resin is provided between the first member 400 and the second member 500 so as to cover the wiring 300. In the present embodiment, the wiring 300 is not in contact with the first member 400 and the second member 500, and the entire region from the connection portion for the first electrode to the connection portion for the second electrode is covered with the third member. The third member 600 is not disposed on an inner side of the first member 400 (that is, a side of the first member 400 that is faced to the effective element region 120), and is not disposed on an outer side of the second member 500 (that is, the outer edge side of the second board 200 with respect to the second member 500). The third member 600 overlaps the first member 400 on a side opposite to the effective element region 120 with respect to an apex (the highest position) of the first member 400. In addition, the third member 600 overlaps the second member on a side of the first member 400 with respect to an apex (the highest position) of the second member 500. The third member 600 is made of a resin such as an acrylic resin, an epoxy resin, or a silicone resin. The third member 600 is formed by applying, after solidifying the first member 400 and the second member 500, a resin between the first member 400 and the second member 500 by a dispenser of any type such as an air pulse type, a jet type, or a volumetric type, and solidifying the resin. The third member 600 is formed by applying and curing an appropriate amount of resin so as to cover the wiring 300 but not to overflow to the outside beyond the first member 400 and the second member 500.

The first member 400, the second member 500, and the third member 600 may be formed of substantially the same type of resin material. This is because when the semiconductor apparatus is driven and generates heat or when an environmental temperature of the semiconductor apparatus changes, temperatures of the members may change, and if thermal expansion coefficients are different from each other, a large thermal stress is applied to the wiring 300, and there is a possibility that a bonding portion may be peeled off. The expression “substantially the same type” means that compositions are the same except for unavoidable variations in composition ratio in manufacturing and unavoidable mixing of impurities.

Even in a case where the members are formed using the same type of material, a boundary surface between the first member 400 and the third member 600 and a boundary surface between the second member 500 and the third member 600 can be specified by forming a cross section as shown in FIG. 2 and observing the cross section. Since the third member 600 is applied after the first member 400 and the second member 500 are solidified and exposed to the atmosphere, and is then solidified, the boundary surface that is a trace of a manufacturing process can be observed even in a stacked body of the same type of resin materials.

In a case where the same type of resin material is not used, it is desirable to select resin materials such that an elastic modulus of the third member 600 is substantially the same as an elastic modulus of the first member 400 and an elastic modulus of the second member 500 or is smaller than at least one of the elastic modulus of the first member 400 and the elastic modulus of the second member 500 after curing. The expression “substantially the same elastic moduli” means that the elastic moduli are the same except for unavoidable manufacturing errors and measurement error ranges. In a case where the elastic modulus of the third member 600 is smaller than the elastic moduli of the first member 400 and the second member 500, the vicinities of the first connection point BP1 and the second connection point BP2 can be mechanically protected by walls of the first member 400 and the second member 500 made of a material having a high elastic modulus. Furthermore, a thermal stress applied to the wiring 300 when the temperature changes can be alleviated by a material having a low elastic modulus. Therefore, reliability of electrical connection by the wiring 300 can be improved. For example, a material having an elastic modulus after solidification of 0.4 MPa to 2 MPa may be used for the third member 600.

### Semiconductor Apparatus Manufacturing Method

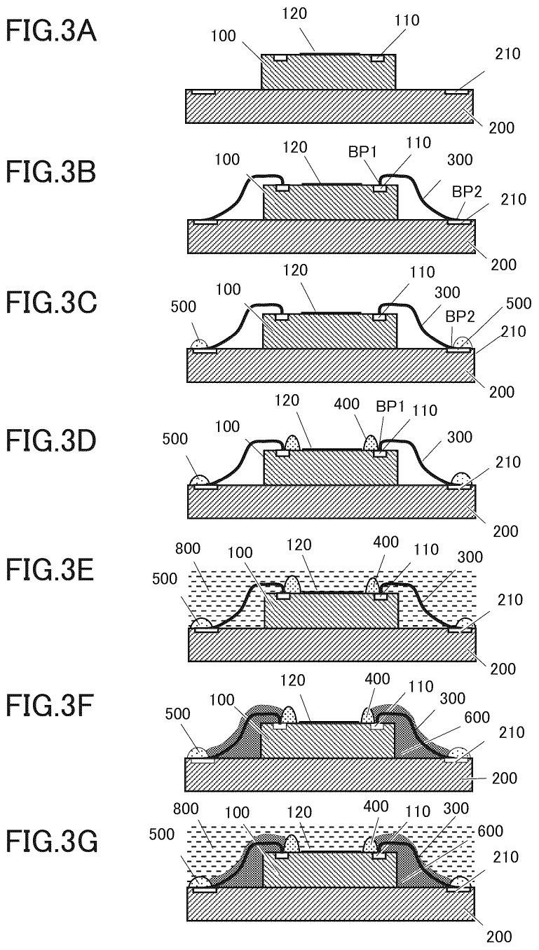

Next, a semiconductor apparatus manufacturing method according to the present embodiment will be described. FIGS. 3A to 3G are schematic diagrams for describing each stage of the semiconductor apparatus manufacturing method.

First, as shown in FIG. 3A, the first board 100 is mounted on and bonded to the second board 200 (mounting step). The first board 100 is placed on the island portion (mounting position) formed at the central portion of the second board 200, and is die-bonded using an adhesive (not shown) while being pressurized. As the adhesive, for example, a die bond paste, a double-sided tape, a die attach film (DAF), a UV delay curable adhesive, or a thermosetting adhesive can be used. In the case of the thermosetting adhesive, the first board 100 is bonded and fixed by using both pressurization and heating.

Next, as shown in FIG. 3B, the first electrode 110 formed in the first board 100 and the second electrode 210 formed in the second board 200 are electrically connected using the wiring 300 made of, for example, a gold wire or a copper wire (connection step). The electrical connection can be made by wire bonding for bonding the wire and the electrodes using both ultrasonic waves and heat.

After the connection step, a covering step of covering the wiring 300 with a resin member is performed. First, as shown in FIG. 3C, the uncured second member 500 is disposed on the side opposite to the first board 100 with respect to the second connection point BP2, that is, on the outer edge side of the second board 200 with respect to the second connection point BP2. As the second member 500, for example, an ultraviolet curable resin made of an acrylic resin, an epoxy resin, a silicone resin, or the like is used, and is applied along the entire periphery of an outer edge of the second board 200 by an application apparatus such as a dispenser. Instead of an ultraviolet curable resin, a thermosetting resin may be applied.

In the present embodiment, the second member 500 functions as a bank (or dam) for storing the third member 600 and preventing the third member 600 from overflowing to the outside so that the low-viscosity third member applied in the subsequent process can cover the wiring 300. Therefore, the second member 500 is formed to have an appropriate height (thickness) such that a sufficient amount of third member 600 can be stored according to a bent shape of the wire-bonded wiring 300 and a height of the apex of the wire-bonded wiring 300.

Application conditions such as a viscosity of the second member 500, a needle diameter of the dispenser, a discharge pressure, and an application speed are set such that the uncured second member 500 does not spread and contaminate the periphery of the second board 200 and the second member 500 having a predetermined height (thickness) can be formed. As long as the second member 500 can be applied to a predetermined position in a predetermined shape, the viscosity of the uncured second member is not limited, but for example, a range of 6 Pa·s to 10 Pa·s may be preferable.

Next, as shown in FIG. 3D, the uncured first member 400 is disposed between the effective element region 120 and the first connection point BP1. As the first member 400, for example, an ultraviolet curable adhesive made of an acrylic resin, an epoxy resin, a silicone resin, or the like is used, and is applied by an application apparatus such as a dispenser so as to be spaced apart from the effective element region 120 along the entire periphery of the effective element region 120. Instead of an ultraviolet curable resin, a thermosetting resin may be applied.

In the present embodiment, the first member 400 functions as a bank (or dam) for preventing the low-viscosity third member 600 applied to cover the wiring 300 in the subsequent process from entering the effective element region 120. Therefore, the first member 400 is formed to have an appropriate height (thickness) such that a sufficient amount of third member 600 can be stored according to the bent shape of the wire-bonded wiring 300 and a height of the apex of the wire-bonded wiring 300.

Application conditions such as a viscosity of the first member 400, a needle diameter of the dispenser, a discharge pressure, and an application speed are set such that the uncured first member 400 does not spread and enter the effective element region 120, and the first member 400 having a predetermined height (thickness) can be formed. As long as the first member 400 can be applied to a predetermined position in a predetermined shape, the viscosity of the uncured first member is not limited, but for example, a range of 6 Pa·s to 10 Pa·s may be preferable.

The height (thickness) of the first member 400 varies depending on the bent shape of the wire-bonded wiring 300 and the height of the apex of the wire-bonded wiring 300, and is, for example, in a range of about 0.3 mm to 2.0 mm from the surface of the first board 100.

Here, the uncured second member 500 is formed and then the uncured first member 400 is formed. However, the uncured second member 500 and the uncured first member 400 may be formed in the reverse order. In a case where the first member 400 or the second member 500 having a predetermined height (thickness) cannot be formed by performing application once, the first member 400 or the second member 500 having a predetermined height (thickness) may be formed by performing application a plurality of times in layers. In some cases, a resin may be cured every time application is performed to form a resin member having a predetermined height (thickness) while suppressing spreading. In addition, if the first member 400 and the second member 500 are formed using the same type of resin, it is not necessary to replace the resin material of the dispenser in the process shown in FIG. 3C and the process shown in FIG. 3D, so that a production process becomes efficient.

Next, a step of curing the uncured first member 400 and the uncured second member 500 will be described. FIG. 3E schematically shows a step of simultaneously irradiating the first member 400 and the second member 500 formed of an ultraviolet curable resin with an ultraviolet ray 800 to cure the first member 400 and the second member 500. The first member 400 and the second member 500 are cured by being simultaneously irradiated with the ultraviolet ray 800 having a wavelength capable of curing the resin from an ultraviolet light source such as a high-pressure mercury lamp or a light emitting diode (LED).

Steps of curing processing for the first member 400 and the second member 500 may be performed separately rather than simultaneously. For example, the second member 500 may be cured immediately after the step of FIG. 3C is performed, and the first member 400 may be cured immediately after the step of FIG. 3D is performed. If the curing processing is performed immediately after the application, the first member 400 and the second member 500 can be cured before being deformed by gravity or the like, so that the first member 400 and the second member 500 can be solidified with high shape accuracy.

In a case where the first member 400 and the second member 500 are formed using an ultraviolet curable acrylic resin, it may be preferable to perform curing by irradiating the first member 400 and the second member 500 with the ultraviolet ray in a nitrogen atmosphere in order to prevent a curing failure due to oxygen. In a case where the first member 400 and the second member 500 are formed using a thermosetting resin instead of an ultraviolet curable resin, it may be preferable to use a fast-curing material in order to shorten a time taken for the curing processing by heating.

Next, as shown in FIG. 3F, the uncured third member 600 is disposed between the cured first member 400 and the cured second member 500. As the third member 600, for example, an ultraviolet curable resin made of an acrylic resin, an epoxy resin, a silicone resin, or the like is used, and is applied along the entire periphery of an outer edge of the first member 400 by an application apparatus such as a dispenser. Instead of an ultraviolet curable resin, a thermosetting resin may be applied.

The first member 400 and the second member 500 after curing function as banks (dams) for storing the uncured third member 600, and a sufficient amount of uncured third member 600 for covering the wiring 300 is applied between the first member 400 and the second member 500. In a case where the sufficient amount for covering the wiring 300 cannot be applied by performing application once, the application may be performed a plurality of times in layers.

In the present embodiment, the third member 600 is formed using a resin having a lower viscosity at the time of application (before curing) than a resin used for forming the first member 400 and the second member 500. Since it is necessary to form the first member 400 and the second member 500 having heights (thicknesses) sufficient to function as the banks (dams) for storing the uncured third member 600, the first member 400 and the second member 500 are formed by applying a resin having a high viscosity and difficult to flow. On the other hand, in order to achieve the function of protecting the wiring 300, it is necessary that the third member 600 reliably covers the wiring 300 and fills a space between a plurality of wirings 300 arranged at a high density such that bubbles or voids are not present between the wirings 300. In order to reliably fill the space between the plurality of wirings 300 arranged at a high density and suppress generation of the bubbles or voids, it is advantageous to use a resin having a low viscosity. In general, when a resin having a low viscosity and high fluidity is applied to achieve a height (application thickness), the resin easily spreads to the surroundings. However, in the present embodiment, the first member 400 and the second member 500 after curing function as the banks (dams) for storing the resin of the third member before curing. Therefore, even if the wiring 300 is covered using a resin having a low viscosity and high fluidity, the resin of the third member before curing does not overflow over the bank (dam) to the surroundings.

As long as the wiring 300 can be covered and gaps between the wirings 300 can be filled without generating the bubbles or voids, the viscosity of the resin used for the third member 600 before curing is not limited, but for example, the viscosity may be in a range of 4 Pa·s to 6 Pa·s.

In the present embodiment, in comparison of the viscosities at the time of application (before curing), a resin material having a viscosity relatively lower than those of the first member 400 and the second member 500 is used for the third member 600, but it may be preferable that the resin materials are the same type (same composition). This is because if the first member 400, the second member 500, and the third member 600 are formed of the same type of resin material, the thermal expansion coefficients after curing can be the same as each other, and thus, even if the temperature changes when using the semiconductor apparatus, a large thermal stress can be prevented from being applied to the wiring 300.

In general, since the viscosity of the resin material before curing varies depending on the temperature, it is sufficient if application is performed by changing the temperature so as to obtain different viscosities when forming each member. For example, in the case of a resin material whose viscosity decreases as the temperature increases, it is sufficient if, when applying the third member 600, the resin material is applied at a temperature higher than that at the time of applying the first member 400 and the second member 500.

However, the embodiment is not limited to a mode in which the same type (same composition) of resin material is used for the first member 400, the second member 500, and the third member 600, and resin materials having different compositions may be used as long as viscosities before solidification are different.

Next, a step of curing the uncured third member 600 will be described. FIG. 3G schematically shows a step of irradiating the third member 600 formed of an ultraviolet curable resin with the ultraviolet ray 800 to cure the third member 600. The third member 600 is cured by being irradiated with the ultraviolet ray 800 having a wavelength capable of curing the resin from an ultraviolet light source such as a high-pressure mercury lamp or an LED.

In a case where the third member 600 is formed using an ultraviolet curable acrylic resin, it may be preferable to perform curing by irradiating the third member 600 with the ultraviolet ray in a nitrogen atmosphere in order to prevent a curing failure due to oxygen. In a case where the third member 600 is formed using a thermosetting resin instead of an ultraviolet curable resin, it may be preferable to use a fast-curing resin material in order to shorten a time taken for the curing processing. The semiconductor apparatus according to the embodiment is manufactured by performing the above processing steps.

As described above, in the semiconductor apparatus according to the present embodiment, the third member 600 having a relatively low viscosity fills a space between the first member 400 and the second member 500 formed in advance using a resin having a relatively high viscosity. As a result, it is possible to suppress generation of the bubbles or voids when forming a covering structure for protecting the wiring 300 using a resin. By forming the first member 400 and the second member 500 in advance, the third member 600 is prevented from spreading and contaminating the effective element region 120 formed on the first board 100 and an outer edge portion of the second board 200. According to the present embodiment, it is possible to provide the semiconductor apparatus with high reliability and high quality.

### Second Embodiment

In the first embodiment, the first member 400 is disposed so as to be spaced apart from the first connection point BP1, the second member 500 is disposed so as to be spaced apart from the second connection point BP2, and the wiring 300 is covered only with the third member 600, but the embodiment according to the present disclosure is not limited thereto.

Hereinafter, a second embodiment will be described, but a description of matters common to the first embodiment will be simplified or omitted. In the second embodiment, for example, a first connection point BP1 may be covered with a first member 400. Alternatively, a second connection point BP2 may be covered with a second member 500. A wiring 300 may be covered with the first member and a third member, may be covered with the second member and the third member, or may be covered with the first member, the second member, and the third member. In other words, in the wiring 300, the entire region from a connection portion for a first electrode 110 to a connection portion for a second electrode 210 is covered with a resin member including at least a third member 600.

A schematic plan view of a semiconductor apparatus according to the second embodiment is represented as in FIG. 1 similarly to the first embodiment, and thus a description thereof is omitted. Similarly to the first embodiment, the semiconductor apparatus according to the second embodiment also includes a first board 100 serving as a semiconductor chip, a second board 200 serving as a circuit board, the wiring 300, the first member 400, the second member 500, and the third member 600.

### First Example

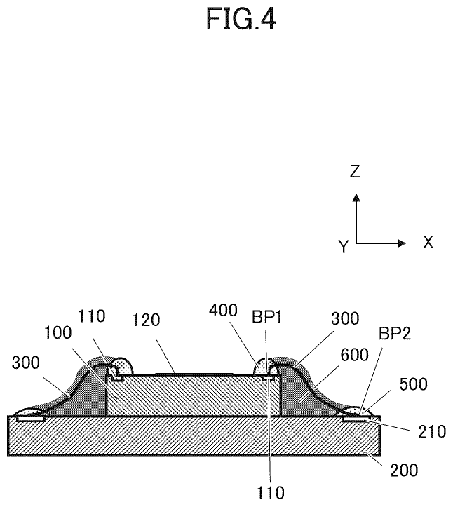

FIG. 4 is a schematic cross-sectional view showing a cross section of a semiconductor apparatus according to a first example of the second embodiment taken along line A-A shown in FIG. 1. Also, in a case where the semiconductor apparatus is cut in a direction that passes through the center of the semiconductor apparatus and is orthogonal to line A-A, a cross-sectional view similar to FIG. 4 may be obtained.

In the example shown in FIG. 4, similarly to the first embodiment, the first member 400 is disposed so as to be spaced apart from an effective element region 120. However, unlike the first embodiment, the first member 400 is formed so as to cover the entire first electrode 110 including the first connection point BP1 and a part of the wiring 300. When the first member 400 protrudes to the outside from an outer edge of the first board 100, that is, from a side surface of the first board, there is a possibility that voids or bubbles are generated when forming the third member 600. Therefore, the first member 400 is desirably disposed on an inner side of the outer edge of the first board 100.

Similarly to the first embodiment, the second member 500 is disposed so as to be spaced apart from the first board 100. However, unlike the first embodiment, the second member 500 is formed so as to cover the entire second electrode 210 including the second connection point BP2 and a part of the wiring 300.

The first member 400, the second member 500, and the third member 600 are may be formed of the same type of resin material. This is because when the semiconductor apparatus is driven and generates heat or when an environmental temperature of the semiconductor apparatus changes, temperatures of the members may change, and if thermal expansion coefficients are different from each other, a large thermal stress is applied to the wiring 300, and there is a possibility that a bonding portion may be peeled off.

Even in a case where the members are formed using the same type of material, a boundary surface between the first member 400 and the third member 600 and a boundary surface between the second member 500 and the third member 600 can be specified by forming a cross section as shown in FIG. 4 and observing the cross section. Since the third member 600 is applied after the first member 400 and the second member 500 are solidified and exposed to the atmosphere, and is then solidified, the boundary surface can be observed as a trace of a manufacturing process even in a stacked body of the same type of resin materials.

In a case where the same type of resin material is not used, it is desirable to select resin materials such that an elastic modulus of the third member 600 is equal to or smaller than an elastic modulus of the first member 400 and an elastic modulus of the second member 500. In a case where the elastic modulus of the third member 600 is relatively small, the vicinities of the first connection point BP1 and the second connection point BP2 can be mechanically protected by a material having a high elastic modulus. Furthermore, a thermal stress applied to the wiring 300 when the temperature changes can be alleviated by a material having a low elastic modulus. Therefore, reliability of electrical connection by the wiring 300 can be improved. For example, a material having an elastic modulus after solidification of 0.4 MPa to 2 MPa is preferably used for the third member 600.

In order to manufacture the semiconductor apparatus according to the second embodiment, manufacturing can be performed by a procedure shown in FIGS. 3A to 3G similarly to the first embodiment. In comparison of the viscosities at the time of application (before curing), a resin material having a viscosity relatively lower than those of the first member 400 and the second member 500 is used for the third member 600. However, in the second embodiment, the second connection point BP2 and the wiring 300 in the vicinity thereof are covered with the second member 500 at the stage shown in FIG. 3C, and the first connection point BP1 and the wiring 300 in the vicinity thereof are covered with the first member 400 at the stage shown in FIG. 3D. When one or both of the first member 400 and the second member 500 are solidified, the wiring 300 is mechanically supported in the vicinity of the connection point by the solidified resin, and a posture of the wiring 300 is stabilized. Therefore, in the subsequent manufacturing process, problems such as falling of the wiring 300, a short circuit between adjacent wirings due to deformation, and peeling from the electrode hardly occur, and a manufacturing yield can be improved.

### Second Example

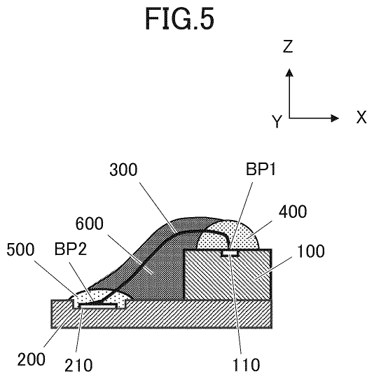

FIG. 5 is a schematic cross-sectional view showing a part of a cross section of a semiconductor apparatus according to a second example of the second embodiment taken along line A-A shown in FIG. 1. A description of matters common to the first example will be omitted. In the second example, in order to ensure that the second member 500 covers the entire second electrode 210 including the second connection point BP2 and a part of the wiring 300 and does not unnecessarily spread, a recess is provided in the second board 200, and the second electrode 210 is disposed in the recess.

In the second board 200, the recess is provided around the first board 100 in plan view, and the second electrode 210 is provided at the bottom of the recess. The second electrode 210 is disposed at a position lower than a mounting surface on which the first board 100 is mounted.

By disposing the second electrode 210 at the bottom of the recess, when the second member 500 is applied in the process shown in FIG. 3C, the resin can be applied without excess or deficiency so as to cover the entire second electrode 210 including the second connection point BP2 and a part of the wiring 300.

In addition, in order to improve accuracy of a position and a posture when mounting the first board 100 on the second board 200, it is necessary to sufficiently increase flatness and parallelism of an island portion to which the first board 100 is fixed. If the second electrode 210 is formed on the same surface when performing polishing to enhance surface accuracy of the island portion, problems such as insufficient surface accuracy of the island portion due to trouble in polishing and insufficient thickness of the second electrode 210 due to scraping may occur. Therefore, it is easy to improve the surface accuracy of the island portion and to achieve the thickness of the second electrode 210 by disposing the second electrode 210 at a position lower than the island portion.

### Third Example

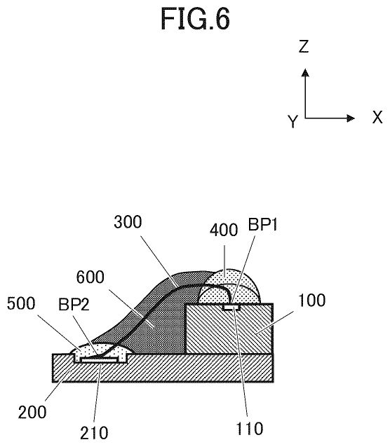

FIG. 6 is a schematic cross-sectional view showing a part of a cross section of a semiconductor apparatus according to a third example of the second embodiment taken along line A-A shown in FIG. 1. A description of matters common to the first example will be omitted. In the third example, in order to ensure that the first member 400 covers the entire first electrode 110 including the first connection point BP1 and a part of the wiring 300, the first member 400 is formed by applying a resin a plurality of times. FIG. 6 shows an example in which the first member 400 is formed by applying a resin twice, but the number of times of application is arbitrary.

The first member 400 is provided so as to be higher than the highest position of the wiring 300 in a Z direction. Therefore, when a foreign substance approaches the wiring 300 from the Z direction, the first member 400 can protect the wiring 300. When increasing the height of the first member 400 by applying a resin a plurality of times, it is preferable to cure the resin for each application in order to enhance shape accuracy.

### Fourth Example

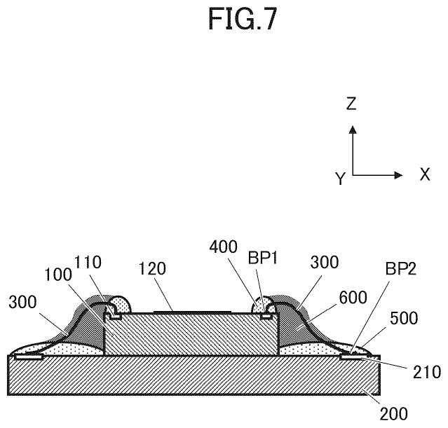

FIG. 7 is a schematic cross-sectional view showing a cross section of a semiconductor apparatus according to a fourth example of the second embodiment taken along line A-A shown in FIG. 1. Also, in a case where the semiconductor apparatus is cut in a direction that passes through the center of the semiconductor apparatus and is orthogonal to line A-A, a cross-sectional view similar to FIG. 7 may be obtained. A description of matters common to the first example will be omitted. In the fourth example, the second member 500 is formed so as to cover the entire second electrode 210 including the second connection point BP2 and a part of the wiring 300. However, unlike the above examples, the second member 500 extends on the second board 200 so as to be in contact with the side surface of the first board 100.

Although the first board 100 is mounted on the second board 200, a slight gap or a step may be generated at an interface between the first board 100 and the second board 200. In a case where the second member 500 is spaced apart from the first board 100 as in the first example, the bubbles may be generated in such a gap or step when the third member 600 is applied. Therefore, in the fourth example, the second member 500 is applied so as to be in contact with the side surface of the first board 100 to cover or fill the gap or the step, and the third member 600 is formed thereon.

In the fourth example, in comparison of the viscosities at the time of application (before curing), a resin material having a viscosity relatively lower than that of the first member 400 may be used for the second member 500. As the third member 600, a resin material having a viscosity relatively lower than those of the first member 400 and the second member 500 is used similarly to the other examples.

### Third Embodiment

In the first embodiment and the second embodiment, an example in which the first electrode 110 and the second electrode 210 are disposed with a relatively large height difference in a direction (Z direction) orthogonal to the main surface of the first board has been described. A third embodiment shows a semiconductor apparatus having a configuration in which a height difference between a first electrode 110 and a second electrode 210 is reduced. When the height difference between the first electrode 110 and the second electrode 210 is reduced, a curvature at which a wiring 300 is curved can be reduced, and the maximum height of the wiring 300 can also be reduced, so that a third member 600 for covering the wiring 300 can be easily formed. A description of matters common to the first or second embodiment will be omitted.

A schematic plan view of the semiconductor apparatus according to the third embodiment is represented as in FIG. 1 similarly to the first embodiment, and thus a description thereof is omitted. Similarly to the first embodiment, the semiconductor apparatus according to the third embodiment also includes a first board 100 serving as a semiconductor chip, a second board 200 serving as a circuit board, the wiring 300, a first member 400, a second member 500, and the third member 600.

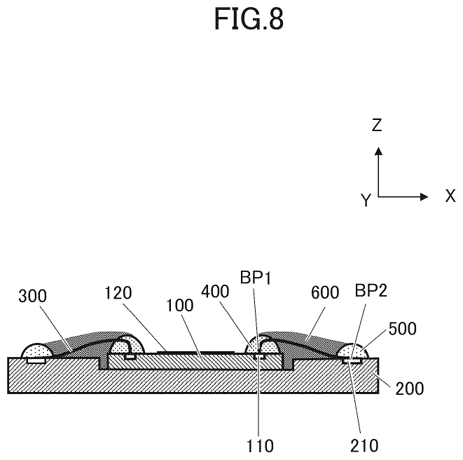

FIG. 8 is a schematic cross-sectional view showing a cross section of the semiconductor apparatus according to the third embodiment taken along line A-A shown in FIG. 1. Also, in a case where the semiconductor apparatus is cut in a direction that passes through the center of the semiconductor apparatus and is orthogonal to line A-A, a cross-sectional view similar to FIG. 8 may be obtained.

In the present embodiment, a recess is provided in the second board 200 such that the height difference between the first electrode 110 and the second electrode 210 is reduced when the first board 100 is mounted on the second board 200, and an island portion on which the first board 100 is mounted is disposed at the bottom of the recess. That is, the island portion (a mounting surface for the first board) is disposed at a position lower than the second electrode 210.

With such a configuration, when the height difference between the first electrode 110 and the second electrode 210 is reduced, the wiring 300 connecting the first electrode 110 and the second electrode 210 can be installed along a curve having a low apex height and a small curvature. Since a height of the wiring 300 in the Z direction is reduced, a risk that the wiring 300 comes into contact with a foreign substance is reduced. Furthermore, since an angle formed between the wiring and an electrode surface is reduced at a bonding portion with the electrode, stress applied to the bonding portion can be reduced, and reliability of electrical connection can be enhanced.

In a case where the maximum height of the wiring 300 is small, formation of the third member 600 using a resin having a low viscosity to cover the wiring 300 becomes easy. A height of the second member 500 or the first member 400 that functions as a bank (or dam) for storing the third member 600 and preventing the third member 600 from flowing out can be reduced. In addition, since an amount of the third member 600 required to cover the wiring 300 and a time required for an application process can be reduced, a manufacturing cost of the semiconductor apparatus can be reduced.

### Fourth Embodiment

In the first to third embodiments, the first board 100 serving as the semiconductor chip and the second board 200 serving as the single circuit board are integrated with each other and electrically connected to each other via the wire. However, the embodiment according to the present disclosure is not limited thereto.

A semiconductor chip may be electrically connected to a plurality of boards (circuit boards or semiconductor chips) via a wire. Further, the semiconductor chip may be integrated with the plurality of boards (circuit boards or semiconductor chips).

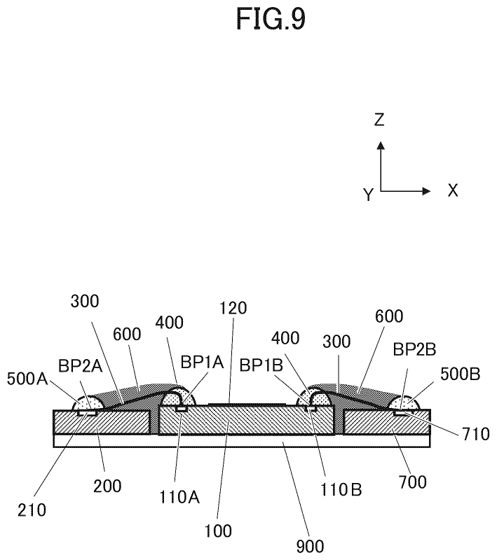

FIG. 9 is a schematic cross-sectional view showing a cross section of a semiconductor apparatus according to a fourth embodiment. A description of matters common to any one of the first to third embodiments will be omitted. In the example shown in FIG. 9, the semiconductor apparatus includes a first board 100 serving as the semiconductor chip, a second board 200 serving as the circuit board, a third board 700 serving as the circuit board, a base board 900, and a wiring 300. In this example, the first board 100, the second board 200, and the third board 700 are all bonded to the base board, and are integrated. Here, if the entire portion in which the second board 200, the base board 900, and the third board 700 are integrated is regarded as the second board, it can be said that the first board is mounted on the second board. FIG. 9 shows an example, and the number, arrangement, and fixing method of the boards in the fourth embodiment are not limited to this example.

A first electrode 110A formed in the first board 100 is electrically connected to a second electrode 210 formed in the second board 200 by the wiring 300. A connection point BP1A between the first electrode 110A and the wiring 300 is covered with a first member 400, and a connection point BP2A between the second electrode 210 and the wiring 300 is covered with a second member 500A.

A first electrode 110B formed in the first board 100 is electrically connected to a second electrode 710 formed in the third board 700 by the wiring 300. A connection point BP1B between the first electrode 110B and the wiring 300 is covered with the first member 400, and a connection point BP2B between the second electrode 710 and the wiring 300 is covered with a second member 500B.

All the wirings 300 are covered with a resin member including a third member 600. The third member 600 is formed using a resin having a lower viscosity at the time of application (before curing) than a resin used for forming the first member 400, the second member 500A, and the second member 500B. When applying the third member 600 having a low viscosity, the first member 400, the second member 500A, and the second member 500B function as banks (dams) for storing the uncured third member 600.

In the semiconductor apparatus according to the present embodiment, the first member 400, the second member 500A, and the second member 500B are formed in advance by applying a resin having a high viscosity, and the third member 600 having a low viscosity fills a space therebetween. As a result, it is possible to suppress generation of the bubbles or voids when forming a covering structure for protecting the wiring 300 using a resin. In addition, the third member is prevented from spreading and contaminating an effective element region 120 formed on the first board 100, an outer edge portion of the second board 200, and an outer edge portion of the third board 700. According to the present embodiment, it is possible to provide the semiconductor apparatus with high reliability and high quality.

### Fifth Embodiment

In the first to fourth embodiments, an example in which arrangement of the electrodes is in-line arrangement on a straight line in the circuit board connected to the semiconductor chip by the wire has been described, but the embodiment according to the present disclosure is not limited thereto. As a fifth embodiment, an example in which electrodes connected to a semiconductor chip by a wire are arranged in a staggered manner on a circuit board will be described. A description of matters common to any one of the first to fourth embodiments will be simplified or omitted.

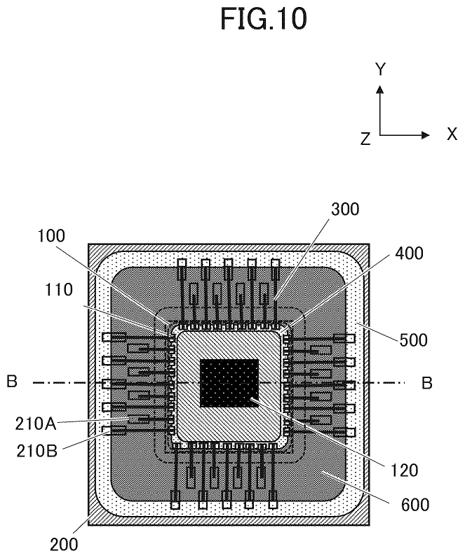

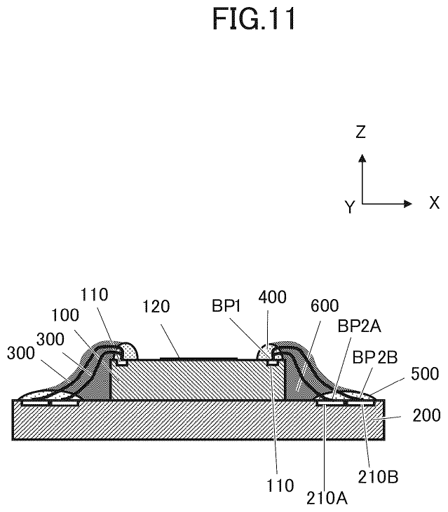

FIG. 10 is a schematic plan view of a semiconductor apparatus according to the fifth embodiment, and FIG. 11 is a schematic cross-sectional view showing a cross section of the semiconductor apparatus taken along line B-B shown in FIG. 10. The semiconductor apparatus according to the present embodiment includes a first board 100 serving as the semiconductor chip and a second board 200 serving as the circuit board. Also, in a case where the semiconductor apparatus is cut in a direction that passes through the center of the semiconductor apparatus shown in FIG. 10 and is orthogonal to line B-B, a cross-sectional view similar to FIG. 11 may be obtained.

When the number of first electrodes 110 for wire bonding disposed in the first board 100 serving as the semiconductor chip increases and an arrangement pitch decreases, it is necessary to decrease an arrangement pitch of second electrodes for wire bonding arranged in the second board 200 serving as the circuit board accordingly. However, on a circuit board side, since there are restrictions on an electrode size, a layout of a wiring pattern, and the like, it may be difficult to arrange a large number of second electrodes at a high density in in-line arrangement.

In the present embodiment, even if a large number of first electrodes 110 are formed at a small arrangement pitch in the semiconductor chip, the second electrodes of the circuit board are alternately arranged in a staggered manner, and thus, a wiring 300 can be wire-bonded without any problem.

In the example shown in FIGS. 10 and 11, second electrodes 210A of an inner row and second electrodes 210B of an outer row are alternately arranged along each side of the second board 200. The second electrodes are not limited to two rows of the inner row and the outer row and may be arranged in three or more rows.

A first connection point BP1 between the first electrode 110 of the first board 100 and the wiring 300 is covered with a first member 400 as in the second embodiment. A second connection point BP2A between the second electrode 210A of the second board 200 and the wiring 300 and a second connection point BP2B between the second electrode 210B and the wiring 300 are covered with a second member 500. The wiring 300 is covered with a resin member including at least a third member 600.

As in the other embodiments, in the fifth embodiment, in comparison of the viscosities at the time of application (before curing), a resin material having a viscosity relatively lower than those of the first member 400 and the second member 500 is used for the third member 600. The first member 400 and the second member 500 are formed in advance by applying a resin having a high viscosity, and the third member 600 having a low viscosity fills a space between the first member 400 and the second member 500. As a result, it is possible to suppress generation of bubbles or voids when forming a covering structure for protecting the wiring 300 using a resin. By forming the first member 400 and the second member 500 in advance, the third member 600 is prevented from spreading and contaminating the effective element region 120 formed on the first board 100 and an outer edge portion of the second board 200. According to the present embodiment, it is possible to provide the semiconductor apparatus with high reliability and high quality even when the number of first electrodes 110 for wire bonding arranged in the first board 100 serving as the semiconductor chip is large and the arrangement pitch is small.

### Sixth Embodiment

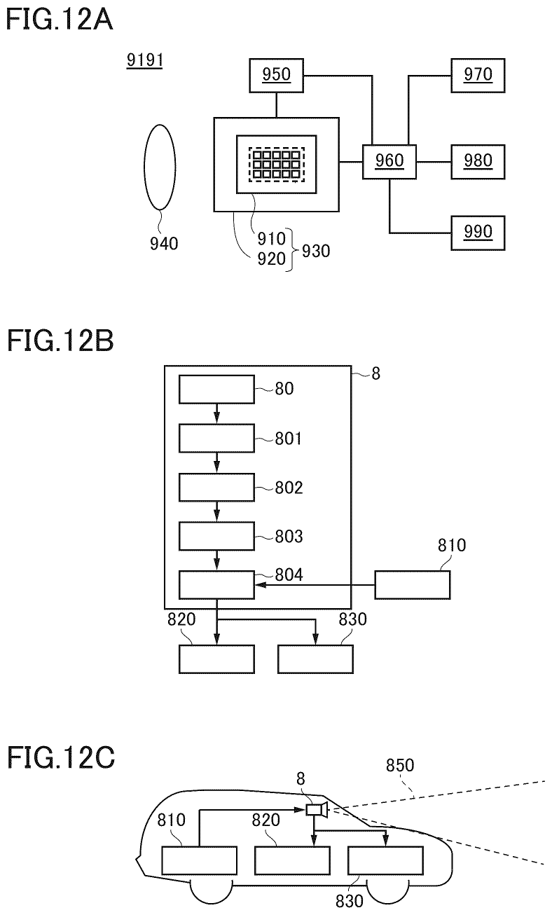

As a sixth embodiment, equipment including the semiconductor apparatus according to any one of the above-described embodiments will be described. FIG. 12A is a schematic diagram for describing equipment 9191 including an imaging apparatus 930 including a semiconductor apparatus 910 according to the above-described embodiment. The equipment 9191 including the imaging apparatus 930 will be described in detail.

The imaging apparatus 930 includes the semiconductor apparatus 910 in which a first board 100 serving as a photoelectric conversion apparatus and a second board 200 serving as a circuit board including at least one of a memory circuit and a logic circuit are integrated. The semiconductor apparatus 910 is a semiconductor apparatus according to any one of the above-described embodiments. Furthermore, the imaging apparatus 930 includes a casing 920 that holds the semiconductor apparatus 910.

The equipment 9191 can include at least one of an optical apparatus 940, a control apparatus 950, a processing apparatus 960, a display apparatus 970, a storage apparatus 980, and a mechanical apparatus 990, in addition to the imaging apparatus 930. The optical apparatus 940 is, for example, a lens, a shutter, or a mirror provided corresponding to the imaging apparatus 930. The control apparatus 950 controls the imaging apparatus 930. The control apparatus 950 is, for example, a semiconductor apparatus such as an application specific integrated circuit (ASIC).

The processing apparatus 960 processes a signal output from the imaging apparatus 930. The processing apparatus 960 is a semiconductor apparatus such as a central processing unit (CPU) or an ASIC for configuring a digital front end (DFE). The display apparatus 970 is an EL display apparatus or a liquid crystal display apparatus that displays information (image) obtained by the imaging apparatus 930. The storage apparatus 980 is a magnetic device or a semiconductor device that stores information (image) obtained by the imaging apparatus 930. The storage apparatus 980 is a volatile memory such as a static random-access memory (SRAM) or a dynamic random-access memory (DRAM), or a nonvolatile memory such as a flash memory or a hard disk drive.

The mechanical apparatus 990 includes a movable unit or a propulsion unit such as a motor or an engine. In the equipment 9191, a signal output from the imaging apparatus 930 is displayed on the display apparatus 970 or is transmitted to the outside by a communication apparatus (not shown) included in the equipment 9191. Therefore, the equipment 9191 may further include the storage apparatus 980 and the processing apparatus 960 separately from a storage circuit and an arithmetic circuit of the imaging apparatus 930. The mechanical apparatus 990 may be controlled based on a signal output from the imaging apparatus 930.

Furthermore, the equipment 9191 is suitable for electronic equipment such as an information terminal (for example, a smartphone or a wearable terminal) having an imaging function or a camera (for example, an interchangeable lens camera, a compact camera, a video camera, or a surveillance camera). The mechanical apparatus 990 in the camera can drive components of the optical apparatus 940 for zooming, focusing, and shutter operations. Alternatively, the mechanical apparatus 990 in the camera can move the imaging apparatus 930 for a vibration-proof operation.

Furthermore, the equipment 9191 may be transportation equipment such as a vehicle, a ship, or a flying body. The mechanical apparatus 990 in the transportation equipment can be used as a movement apparatus. The equipment 9191 serving as the transportation equipment is suitable for transporting the imaging apparatus 930 and assisting and/or automating driving (steering) by the imaging function. The processing apparatus 960 for assisting and/or automating the driving (steering) can perform processing for operating the mechanical apparatus 990 serving as the movement apparatus based on information obtained by the imaging apparatus 930. Alternatively, the equipment 9191 may be medical equipment such as an endoscope, measurement equipment such as a distance measurement sensor, analytical equipment such as an electron microscope, office equipment such as a copying machine, or industrial equipment such as a robot. According to the above-described embodiment, it is possible to stably acquire an image with favorable characteristics.

Therefore, if the imaging apparatus 930 according to the present embodiment is used for the equipment 9191, the value of the equipment can also be improved. For example, it is possible to obtain excellent performance when the imaging apparatus 930 is mounted on the transportation equipment and performs imaging of the outside of the transportation equipment or measurement of an external environment. Therefore, in manufacturing and selling the transportation equipment, it is advantageous to determine to mount the semiconductor apparatus according to the present embodiment on the transportation equipment in order to enhance the performance of the transportation equipment itself. In particular, the imaging apparatus 930 is suitable for transportation equipment that performs driving assistance and/or automated driving of the transportation equipment by using information obtained by the semiconductor apparatus. Implementation in a vehicle, a ship, a flying body, and the like is not limited to application to equipment practically used for transportation purposes, and can be suitably applied to, for example, a drone or the like that performs aerial imaging for various purposes including inspection of buildings and agricultural facilities, monitoring of natural phenomena, and the like.

A photoelectric conversion system and a mobile body according to the present embodiment will be described with reference to FIGS. 12B and 12C. FIG. 12B shows an example of the photoelectric conversion system related to an in-vehicle camera. A photoelectric conversion system 8 includes a photoelectric conversion apparatus 80. The photoelectric conversion apparatus 80 is a photoelectric conversion apparatus serving as an electronic component including the semiconductor apparatus described in the above embodiment.

The photoelectric conversion system 8 includes an image processing unit 801 that performs image processing on a plurality of pieces of image data acquired by the photoelectric conversion apparatus 80, and a parallax acquisition unit 802 that calculates a parallax (a phase difference of a parallax image) from the plurality of pieces of image data acquired by the photoelectric conversion system 8. Furthermore, the photoelectric conversion system 8 includes a distance acquisition unit 803 that calculates a distance to a target object based on the calculated parallax, and a collision determination unit 804 that determines whether or not there is a possibility of collision based on the calculated distance. Here, the parallax acquisition unit 802 and the distance acquisition unit 803 are examples of a distance information acquisition unit that acquires distance information to the target object. That is, the distance information is information regarding the parallax, a defocus amount, the distance to the target object, and the like. The collision determination unit 804 may determine the possibility of collision by using any one of these pieces of distance information. The distance information acquisition unit may be implemented by dedicated hardware or may be implemented by a software module. Alternatively, the distance information acquisition unit may be implemented by a field programmable gate array (FPGA), an application specific integrated circuit (ASIC), or the like.

The photoelectric conversion system 8 is connected to a vehicle information acquisition apparatus 810, and can acquire vehicle information such as a vehicle speed, a yaw rate, and a steering angle. In addition, the photoelectric conversion system 8 is connected to a control electronic control unit (ECU) 820 which is a control apparatus that outputs a control signal for generating a braking force on the vehicle based on a determination result of the collision determination unit 804. The photoelectric conversion system 8 is also connected to a warning apparatus 830 that issues a warning to a driver based on the determination result of the collision determination unit 804. For example, in a case where the determination result of the collision determination unit 804 indicates that the possibility of collision is high, the control ECU 820 performs vehicle control to avoid collision and reduce damage by applying a brake, returning an accelerator, reducing an engine output, or the like. The warning apparatus 830 issues a warning to a user by emitting warnings such as sound, displaying warning information on a screen of a car navigation system or the like, providing vibrations to a seat belt or a steering wheel, or the like.

In the present embodiment, the photoelectric conversion system 8 images the periphery of the vehicle, for example, an area in front of or behind the vehicle. FIG. 12C shows the photoelectric conversion system in the case of imaging the area (imaging range 850) in front of the vehicle. The vehicle information acquisition apparatus 810 sends an instruction to the photoelectric conversion system 8 or the photoelectric conversion apparatus 80. With such a configuration, accuracy of distance measurement can be further improved.

In the above description, an example of performing control to prevent collision with another vehicle has been described, but the present technology is also applicable to control for performing automated driving following another vehicle, control for performing automated driving so as not to stray from a lane, and the like. Furthermore, the photoelectric conversion system is not limited to the vehicle, and can be applied to a mobile body (mobile apparatus) such as a ship, an aircraft, or an industrial robot, for example. In addition, the present technology can be applied not only to a mobile body but also to equipment that widely uses object recognition, such as an intelligent transport system (ITS).

According to the above-described embodiment, it is possible to provide the semiconductor apparatus with high reliability and high quality. Therefore, for example, responsiveness of control of automated driving of the mobile body can be improved, which can contribute to improvement of safety and the like.

The equipment according to the present embodiment can include at least one of the optical apparatus corresponding to the imaging apparatus including the semiconductor apparatus according to any one of the above-described embodiments, the control apparatus that controls the imaging apparatus, and the processing apparatus that processes information obtained from the imaging apparatus. Alternatively, at least one of the display apparatus that displays information obtained from the imaging apparatus, the storage apparatus that stores information obtained from the imaging apparatus, and the mechanical apparatus that operates based on information obtained from the imaging apparatus can be included.

### Seventh Embodiment

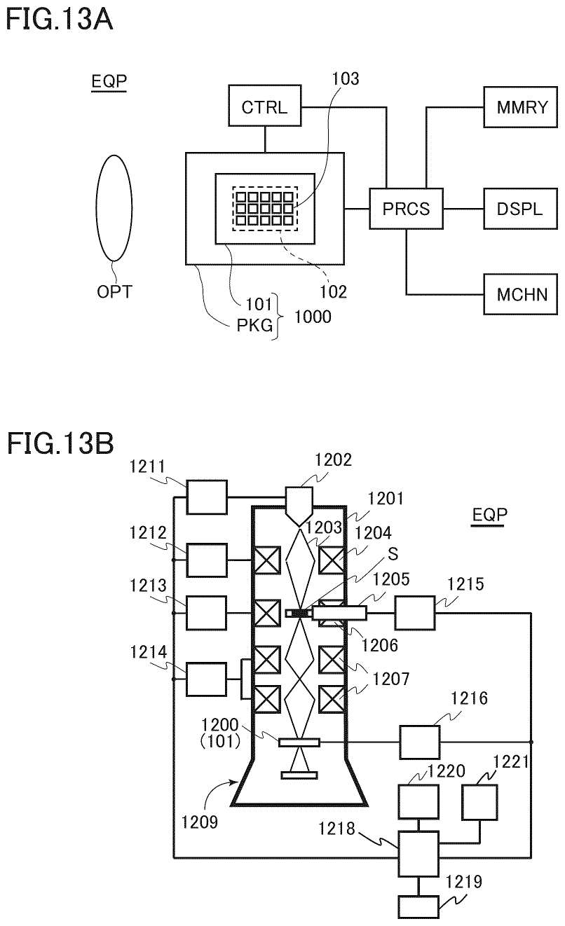

As a seventh embodiment, another example of a radiation imaging system in which the semiconductor apparatus described in any one of the first to fifth embodiments is used as a radiation detector and the radiation detector is incorporated will be described with reference to FIGS. 13A and 13B.

FIG. 13A shows equipment EQP serving as the radiation imaging system including a radiation detector 1000. The radiation detector 1000 includes a package PKG for mounting an imaging element 101 in addition to the imaging element 101 which is a semiconductor device.

The package PKG may include a base to which the imaging element 101 is fixed, a lid such as glass facing the imaging element 101, and a connection member such as a bonding wire or a bump that connects a terminal provided on the base and a terminal provided on the imaging element 101. The imaging element 101 includes a pixel array 102 in which pixels 103 are arranged in a matrix and a peripheral region around the pixel array 102. A peripheral circuit can be provided in the peripheral region.

The equipment EQP may further include at least one of an optical system OPT, a control apparatus CTRL, a processing apparatus PRCS, a display apparatus DSPL, a storage apparatus MMRY, and a mechanical apparatus MCHN. The optical system OPT forms an image of radiation on the radiation detector 1000, and is, for example, a lens, a shutter, or a mirror. The optical system OPT may form an image of a particle beam such as an electron beam or a proton beam on the radiation detector 1000 according to a type of radiation to be handled. The control apparatus CTRL controls the radiation detector 1000, and is, for example, an ASIC. The processing apparatus PRCS processes a signal output from the radiation detector 1000, and is an apparatus such as a central processing unit (CPU) or an ASIC for configuring an analog front end (AFE) or a digital front end (DFE). The display apparatus DSPL is an electroluminescence (EL) display apparatus or a liquid crystal display apparatus that displays information obtained by the radiation detector 1000 in a form of a visible image or the like. The storage apparatus MMRY is a magnetic device or a semiconductor device that stores information obtained by the radiation detector 1000. The storage apparatus MMRY is a volatile memory such as a static random-access memory (SRAM) or a dynamic random-access memory (DRAM), or a nonvolatile memory such as a flash memory or a hard disk drive. The mechanical apparatus MCHN includes a movable unit such as a motor or an engine, or a propulsion unit.

The equipment EQP displays a signal output from the radiation detector 1000 on the display apparatus DSPL or transmits the signal to the outside by a communication apparatus (not shown) included in the equipment EQP. Therefore, the equipment EQP may further include the storage apparatus MMRY and the processing apparatus PRCS separately from a storage circuit and an arithmetic circuit of the radiation detector 1000. The mechanical apparatus MCHN may be controlled based on a signal output from the radiation detector 1000.

The equipment EQP shown in FIG. 13A may be medical equipment such as an endoscope or radiodiagnosis equipment, measurement equipment such as a distance measurement sensor, or analytical equipment such as an electron microscope.

FIG. 13B is a schematic diagram showing a configuration of a transmission electron microscope (TEM) as an example of the equipment EQP. The equipment EQP serving as an electron microscope includes an electron beam source 1202 (electron gun), an application lens 1204, a vacuum chamber 1201 (lens barrel), an objective lens 1206, a magnifying lens system 1207, and a camera 1209 serving as the radiation detector 1000.

The electron beam 1203, which is an energy beam emitted from the electron beam source 1202 (radiation source), is focused by the application lens 1204 and is applied to a sample S serving as an analysis target (imaging target) held by a sample holder. A space through which the electron beam 1203 passes is formed by the vacuum chamber 1201 (lens barrel), and the space is held in vacuum. The radiation detector 1000 is disposed to face the vacuum space through which the electron beam 1203 passes. The electron beam 1203 transmitted through the sample S is enlarged by the objective lens 1206 and the magnifying lens system 1207 and projected onto the radiation detector 1000. An electron optical system for applying the electron beam to the sample S is referred to as an application optical system, and an electron optical system for forming an image of the electron beam transmitted through the sample S on the radiation detector 1000 is referred to as an imaging optical system.

The electron beam source 1202 is controlled by an electron beam source control apparatus 1211. The application lens 1204 is controlled by an application lens control apparatus 1212. The objective lens 1206 is controlled by an objective lens control apparatus 1213. The magnifying lens system 1207 is controlled by a magnifying lens system control apparatus 1214. A control mechanism 1205 of the sample holder is controlled by a holder control apparatus 1215 that controls a drive mechanism of the sample holder.

The electron beam 1203 transmitted through the sample S is detected by a direct detector 1200 of the camera 1209. An output signal from the direct detector 1200 is processed by a signal processing apparatus 1216 and an image processing apparatus 1218 serving as the processing apparatuses PRCS to generate an image signal. The generated image signal (transmitted electron image) is displayed on an image display monitor 1220 and an analysis monitor 1221 corresponding to the display apparatus DSPL.

The camera 1209 is provided in the lower part of the equipment EQP. The camera 1209 includes the direct detector 1200 (direct electron detector). The direct detector 1200 corresponds to the imaging element 101. The direct detector 1200 is provided in the camera 1209 such that at least a part of the camera 1209 is exposed to the vacuum space formed by the vacuum chamber 1201.

Each of the electron beam source control apparatus 1211, the application lens control apparatus 1212, the objective lens control apparatus 1213, the magnifying lens system control apparatus 1214, and the holder control apparatus 1215 is connected to the image processing apparatus 1218. As a result, data can be exchanged with each other in order to set imaging conditions of the electron microscope. For example, an application rate of the electron beam can be set so as to be 0.5 electron/pix/frm or less. In this case, the electron beam source control apparatus 1211 and the image processing apparatus 1218 function as a control unit that controls a radiation application rate. Drive control of the sample holder and observation conditions of each lens can be set by a signal from the image processing apparatus 1218.

An operator prepares the sample S to be imaged, and sets imaging conditions by using an input apparatus 1219 connected to the image processing apparatus 1218. Predetermined data is input to each of the electron beam source control apparatus 1211, the application lens control apparatus 1212, the objective lens control apparatus 1213, and the magnifying lens system control apparatus 1214, and a desired acceleration voltage, magnification, and observation mode are obtained. In addition, the operator inputs conditions such as the number of consecutive visual field images, an imaging start position, and a movement speed of the sample holder to the image processing apparatus 1218 by using the input apparatus 1219 such as a mouse, a keyboard, or a touch panel. Alternatively, the image processing apparatus 1218 may automatically set the conditions without depending on the operator's input. The radiation imaging system described in the seventh embodiment is merely an example, and the semiconductor apparatus described in each of the first to fifth embodiments may be applied to other systems.

Furthermore, in the above embodiments, an example in which an imaging apparatus is applied to the radiation detector or the radiation imaging system has been described. The present technology is not limited thereto, and for example, the method described in each embodiment may be applied to a detector using a single photon avalanche diode (SPAD) and an imaging system including the same.

### OTHER EMBODIMENTS

The present disclosure is not limited to the embodiments described above, and many modifications can be made within the technical idea of the present disclosure. For example, all or some of the different embodiments described above may be combined and implemented.

For example, the first connection point BP1 can be covered with the third member 600 as in the first embodiment, and the second connection point BP2 can be covered with the second member 500 as in the second embodiment. Alternatively, the first connection point BP1 can be covered with the first member 400 as in the second embodiment, and the second connection point BP2 can be covered with the third member 600 as in the first embodiment.

The first member 400 does not have to cover the first electrode 110 and may cover part or all of the first electrode 110. The second member 500 does not have to cover the second electrode 210 and may cover part or all of the second electrode 210. The third member 600 can cover part or all of the wiring 300.

In the second board 200, an opening portion smaller than an outer dimension of the first board 100 may be provided on an island surface on which the first board 100 is mounted.

Further, as in the third embodiment, the recess for mounting the first board 100 may be provided in the second board 200, and as in the second example of the second embodiment, the recess for forming the second electrode 210 may be provided in the second board 200.

The application of the semiconductor apparatus described in each embodiment is not limited to imaging. For example, the present technology is also applicable to a distance measurement apparatus (an apparatus for focus detection, distance measurement using time of flight (TOF), or the like), a photometric apparatus (an apparatus for measuring an incident light quantity or the like), or the like.

The photoelectric conversion apparatus to which the present disclosure can be applied is not limited to a specific form, and may be, for example, any one of a front-illuminated type sensor and a back-illuminated type sensor. Alternatively, the photoelectric conversion apparatus may be a stacked-type photoelectric conversion apparatus in which a semiconductor chip including a light receiving unit and a semiconductor chip including an electric circuit such as a logic circuit are stacked.

A display apparatus to which the present disclosure can be applied is not limited to a specific form, and may be, for example, an organic EL device. A light emitting apparatus to which the present disclosure can be applied is not limited to a specific form, and may be, for example, an LED array or an LD array.

Various types of equipment including the semiconductor apparatus according to the embodiment are also included in the embodiment of the present disclosure. The equipment according to the embodiment can include at least one of six apparatuses including the optical apparatus provided corresponding to the semiconductor apparatus, the control apparatus that controls the semiconductor apparatus, the processing apparatus that processes information obtained from the semiconductor apparatus, the display apparatus that displays information obtained from the semiconductor apparatus, the storage apparatus that stores information obtained from the semiconductor apparatus, and the mechanical apparatus that operates based on information obtained from the semiconductor apparatus.

### OTHER EMBODIMENTS

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-160022, filed Sep. 17, 2024, which is hereby incorporated by reference herein in its entirety.

What is claimed is:

1. A semiconductor apparatus comprising:
a first board serving as a semiconductor chip; and
a second board including an electric circuit and on which the first board is mounted,
wherein the first board includes an effective element region and a first electrode disposed between the effective element region and an outer edge of the first board, having a first member made of a resin and disposed on an outer edge side of the first board with respect to the effective element region,
the second board includes a second electrode disposed between a mounting position of the first board and an outer edge of the second board, having a second member made of a resin and disposed on an outer edge side of the second board with respect to the mounting position of the first board,
a third member that is made of a resin and is in contact with the first member and the second member is disposed between the first member and the second member, is not disposed closer to the effective element region than the first member is, and is not disposed closer to the outer edge side of the second board than the second member is,
the first electrode and the second electrode are electrically connected to each other via a wiring,
a connection portion where the wiring and the first electrode are connected is covered with the first member or the third member,
a connection portion where the wiring and the second electrode are connected is covered with the second member or the third member, and
in the wiring, an entire region from the connection portion for the first electrode to the connection portion for the second electrode is covered with a resin member including at least the third member.

2. The semiconductor apparatus according to claim 1,
wherein the first member, the second member, and the third member are made of substantially same type of material.

3. The semiconductor apparatus according to claim 1,
wherein the first member, the second member, and the third member have substantially same elastic modulus.

4. The semiconductor apparatus according to claim 1,
wherein an elastic modulus of the third member is smaller than at least one of an elastic modulus of the first member and an elastic modulus of the second member.

5. The semiconductor apparatus according to claim 1,
wherein the first member is disposed on an inner side of the outer edge of the first board.

6. The semiconductor apparatus according to claim 1,
wherein the first member covers the connection portion where the wiring and the first electrode are connected.

7. The semiconductor apparatus according to claim 1,
wherein the first member covers at least a part of the first electrode.

8. The semiconductor apparatus according to claim 1,
wherein the second member covers the connection portion where the wiring and the second electrode are connected.

9. The semiconductor apparatus according to claim 1,
wherein the second member covers at least a part of the second electrode.

10. The semiconductor apparatus according to claim 1,
wherein a height of the first member is larger than a height of the wiring in a direction orthogonal to a main surface of the first board.

11. The semiconductor apparatus according to claim 1,
wherein the second board includes a recess, and the second electrode is disposed in the recess.

12. The semiconductor apparatus according to claim 1,
wherein the second member is in contact with the first board.

13. The semiconductor apparatus according to claim 1,
wherein the second board includes a recess, and the first board is mounted in the recess.

14. The semiconductor apparatus according to claim 1,
wherein the second board includes a base board and a third board bonded to the base board,
the third board includes a third electrode disposed between the mounting position of the first board and an outer edge of the third board and has a fourth member made of a resin and disposed on an outer edge side of the third board with respect to the mounting position of the first board, and
the third member that is in contact with the first member and the fourth member is disposed between the first member and the fourth member and is not disposed closer to the outer edge side of the third board than the fourth member is.

15. The semiconductor apparatus according to claim 1,
wherein the first board includes a photoelectric conversion element or a light emitting element in the effective element region.

16. An imaging apparatus comprising: the semiconductor apparatus according to claim 1; and an optical apparatus corresponding to the semiconductor apparatus, wherein the first board includes a photoelectric conversion element in the effective element region.

17. A radiation imaging system comprising:
a radiation source configured to apply radiation to an imaging target; and
the semiconductor apparatus according to claim 1.

18. Equipment comprising:
the semiconductor apparatus according to claim 1; and
at least one of six apparatuses including:
an optical apparatus corresponding to the semiconductor apparatus,
a control apparatus that controls the semiconductor apparatus,
a processing apparatus that processes information obtained from the semiconductor apparatus,
a display apparatus that displays information obtained from the semiconductor apparatus
a storage apparatus that stores information obtained from the semiconductor apparatus, and
a mechanical apparatus that operates based on information obtained from the semiconductor apparatus.

19. A semiconductor apparatus manufacturing method comprising in this order:
a mounting step of mounting a first board serving as a semiconductor chip and including an effective element region and a first electrode on a second board including a second electrode and an electric circuit;
a connection step of electrically connecting the first electrode and the second electrode by a wiring; and
a covering step of covering the wiring with a resin member,
wherein the first electrode is disposed between the effective element region and an outer edge of the first board,
the second electrode is disposed between a position where the first board is mounted and an outer edge of the second board,
the covering step includes:
disposing a first member made of a resin on an outer edge side of the first board with respect to the effective element region and curing the first member;
disposing a second member made of a resin on an outer edge side of the second board with respect to the position where the first board is mounted and curing the second member; and
disposing a third member made of a resin having a viscosity lower than a viscosity of the first member before curing and a viscosity of the second member before curing between the cured first member and the cured second member and curing the third member,
a connection portion where the wiring and the first electrode are connected is covered with the first member or the third member,
a connection portion where the wiring and the second electrode are connected is covered with the second member or the third member, and
in the wiring, an entire region from the connection portion for the first electrode to the connection portion for the second electrode is covered with a resin member including at least the third member.

20. The semiconductor apparatus manufacturing method according to claim 19,
wherein in the covering step,
the third member is not disposed closer to the effective element region than the first member is, and is not disposed closer to the outer edge side of the second board than the second member is.
